(19) United States
(12) Patent Application Publication
(10) Pub. No.: US 2025/0011932 A1
(43) Pub. Date: Jan. 9, 2025

(54) SHOWERHEAD AND APPARATUS FOR PROCESSING A SUBSTRATE INCLUDING THE SAME

(71) Applicant: Samsung Electronics Co., Ltd., Suwon-si (KR)

(72) Inventors: Junho Lee, Suwon-si (KR); Yeontae Kim, Suwon-si (KR); Yihwan Kim, Suwon-si (KR); Youngbok Lee, Suwon-si (KR); Sangchul Han, Suwon-si (KR)

(73) Assignee: Samsung Electronics Co., Ltd., Suwon-si (KR)

(21) Appl. No.: 18/535,442

(22) Filed: Dec. 11, 2023

(30) Foreign Application Priority Data
Jul. 3, 2023 (KR) 10-2023-0085560

(51) Int. Cl. C23C 16/455

(52) U.S. Cl. CPC C23C 16/45565

(57) ABSTRACT

A showerhead includes a showerhead body positioned at an upper surface of a reaction chamber and configured to inject a reaction gas toward a substrate in the reaction chamber and at least one groove in a lower surface of the showerhead body, where the showerhead body is oriented toward the substrate and the lower surface of the showerhead body includes a slanted structure.

### CROSS-REFERENCE TO RELATED APPLICATION

This application is based on and claims priority to Korean Patent Application No. 10-2023-0085560, filed on Jul. 3, 2023 in the Korean Intellectual Property Office, the disclosure of which is incorporated by reference herein in its entirety.

### BACKGROUND

### 1. Field

Example embodiments of the disclosure relate to a showerhead and an apparatus for processing a substrate including the same, and in particular to a showerhead configured to inject a reaction gas to a substrate and an apparatus for processing a substrate including the showerhead.

### 2. Description of Related Art

Generally, an apparatus for processing a substrate may form or etch a layer on the substrate using plasma. The apparatus may include a reaction chamber, an electrostatic chuck (ESC), a showerhead, etc. The plasma may be formed in the reaction chamber. The ESC may support the substrate. The showerhead may inject a reaction gas to the substrate.

As a gap between the substrate and the showerhead is narrowed, a density of the plasma in an edge region of the substrate may be relatively increased. Thus, the plasma may not be uniformly distributed between the substrate and the showerhead. The non-uniform density of the plasma may cause an uneven thickness of the layer.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a showerhead capable of uniformly distributing plasma, as well as an apparatus for processing a substrate including the showerhead.

Additional aspects will be set forth in part in the description which follows and, in part, will be apparent from the description, or may be learned by practice of the presented embodiments.

According to an aspect of an example embodiment, a showerhead may include a showerhead body positioned at an upper surface of a reaction chamber and configured to inject a reaction gas toward a substrate in the reaction chamber and at least one groove in a lower surface of the showerhead body, where the showerhead body is oriented toward the substrate and the lower surface of the showerhead body includes a slanted structure.

According to an aspect of an example embodiment, a showerhead may include a showerhead body positioned an upper surface of a reaction chamber and configured to inject a reaction gas toward a substrate in the reaction chamber and at least one groove in a lower surface of the showerhead body, where the showerhead body is oriented toward the substrate, the lower surface of the showerhead body includes a slanted structure, and the at least one groove includes a first groove in a central portion of the lower surface of the showerhead body, a second groove in an edge portion of the lower surface of the showerhead body, the second groove at least partially surrounding the first groove, and a third groove between the central portion and the edge portion in the lower surface of the showerhead body, such that the third groove is positioned between the first groove and the second groove.

According to an aspect of an example embodiment, an apparatus for processing a substrate may include a reaction chamber configured to receive the substrate, an electrostatic chuck (ESC) in the reaction chamber and configured to support the substrate, and a showerhead positioned at an upper surface of the reaction chamber and configured to inject a reaction gas toward the substrate, where the showerhead includes a showerhead body oriented toward the substrate and at least one groove in a lower surface of the showerhead body, and where the lower surface of the showerhead body includes a slanted structure.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating an apparatus for processing a substrate according to one or more example embodiments;

FIG. 2 is a bottom view illustrating a showerhead of the apparatus in FIG. 1 according to one or more example embodiments;

FIG. 3 is a cross-sectional view illustrating the showerhead in FIG. 2 according to one or more example embodiments;

FIG. 4 is a bottom view illustrating a showerhead according to one or more example embodiments;

FIG. 5 is a cross-sectional view illustrating the showerhead in FIG. 4 according to one or more example embodiments;

FIG. 6 is a cross-sectional view illustrating a showerhead according to one or more example embodiments;

FIG. 7 is a cross-sectional view illustrating a showerhead according to one or more example embodiments;

FIG. 8 is a cross-sectional view illustrating a showerhead according to one or more example embodiments;

FIG. 9 is a bottom view illustrating a showerhead according to one or more example embodiments;

FIG. 10 is a cross-sectional view illustrating the showerhead in FIG. 9 according to one or more example embodiments; and

FIG. 11 is a cross-sectional view illustrating a showerhead according to one or more example embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c

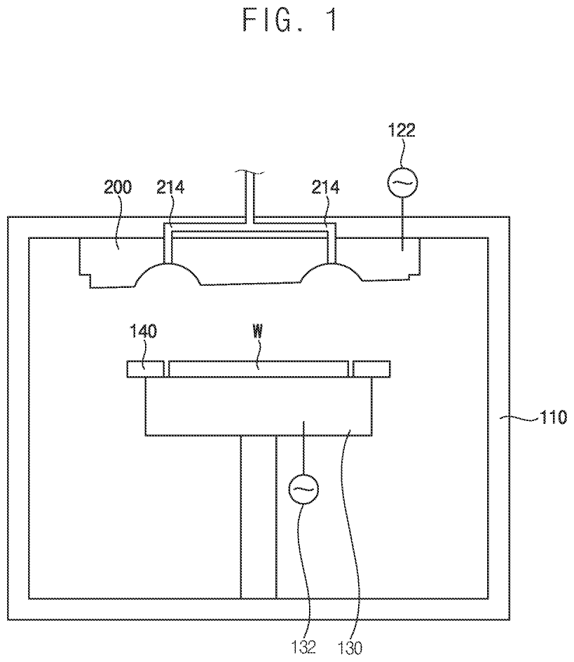

FIG. 1 is a cross-sectional view illustrating an apparatus for processing a substrate according to one or more example embodiments.

Referring to FIG. 1, an apparatus for processing a substrate in accordance with example embodiments may include a capacitively coupled plasma (CCP) apparatus. The CCP apparatus may apply a radio frequency (RF) power to opposite electrodes to generate plasma from a reaction gas using an RF electric field between the electrodes. The CCP apparatus may include various semiconductor fabrication apparatuses configured to process the substrate using the plasma such as a deposition apparatus, an etching apparatus, an ashing apparatus, etc. Particularly, the apparatus may perform a plasma enhanced chemical vapor deposition (PECVD) process for forming an amorphous carbon layer.

The apparatus may include a reaction chamber 110, an electrostatic chuck (ESC) 130, a showerhead 200 and a focus ring 140.

The reaction chamber 110 may have an inner space configured to receive the substrate, such as semiconductor substrate W. The plasma may be formed in the inner space of the reaction chamber 110.

The showerhead 200 may be arranged in an upper region of the reaction chamber 110. The showerhead 200 may include a plurality of injection holes 214 configured to inject a reaction gas into the reaction chamber 110. An RF power supply 122 may be connected to the showerhead 200. Thus, the showerhead 200 may function as an upper electrode.

The ESC 130 may be arranged in a lower region of the reaction chamber 110. An RF power supply 132 may be connected to the ESC 130. Thus, the ESC 130 may function as a lower electrode. A matcher may be arranged between the RF power supply 132 and the ESC 130.

A plurality of lift holes may be formed through the ESC 130 in a vertical direction. A plurality of lift pins may be movably inserted into the lift holes. The lift pins may be configured to support the semiconductor substrate W. The lift pins may be downwardly moved together with the semiconductor substrate W to place the semiconductor substrate W on an upper surface of the ESC 130. Further, the lift pins may be upwardly moved together with the semiconductor substrate W on which a plasma process may be performed.

The focus ring 140 may be arranged at an edge portion of the upper surface of the ESC 130 to surround or at least partially surround the semiconductor substrate W. The focus ring 140 may protect an outer circumferential surface of the semiconductor substrate W from the plasma. Further, the focus ring 140 may concentrate the plasma on an upper surface of the semiconductor substrate W.

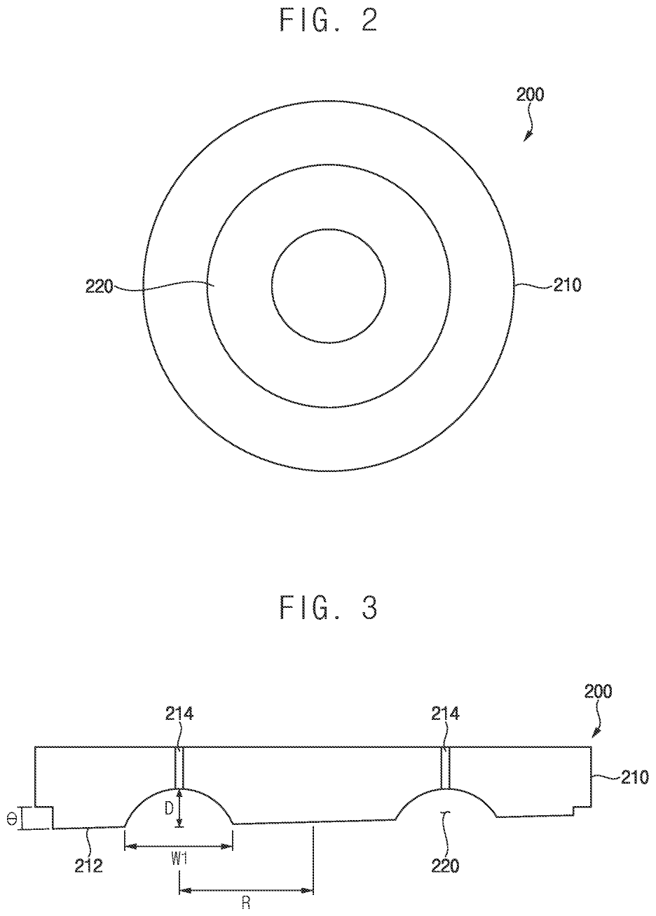

FIG. 2 is a bottom view illustrating a showerhead of the apparatus in FIG. 1 according to one or more example embodiments. FIG. 3 is a cross-sectional view illustrating the showerhead in FIG. 2 according to one or more example embodiments.

Referring to FIGS. 2 and 3, the showerhead 200 may include a showerhead body 210 and a groove 220.

The showerhead body 210 may be positioned over the ESC 130. The injection holes 214 may be formed through the showerhead body 210. The injection holes 214 may extend from an upper surface of the showerhead body 210 to a lower surface in the showerhead body 210.

A slanted structure may be formed on the lower surface 212 of the showerhead body 210. In example embodiments, the slanted structure may be formed on the entire lower surface 212 of the showerhead body 210. Particularly, the slanted structure may be formed on the entire lower surface 212 of the showerhead body 210 along a diameter direction of the showerhead body 210. That is, as shown in FIG. 3, the slanted structure may be slant downward from a right portion to a left portion in the lower surface 212 of the showerhead body 210. An angle of a slanted lower surface 212 of the showerhead 200 with respect to a horizontal plane may be about 0.01° to about 5°, but is not limited thereto.

The groove 220 may be formed on the slanted lower surface 212 of the showerhead body 210. The injection hole 214 may be connected to the groove 220. Thus, a lower end of the injection hole 214 may correspond to the groove 220.

In example embodiments, the groove 220 may have an annular shape, but is not limited thereto. Further, the groove 220 may have a semi-elliptical shape, but is not limited thereto.

The groove 220 may have a center point positioned on a radius R from a center point of the showerhead body 210. The groove 220 may have a depth D measured from the lower surface of the showerhead 200 to an uppermost end of the groove 220. The depth D of the groove 220 may be about 0.1 mm to about 1 mm, but is not limited thereto. Furthermore, the groove 220 may have a width W1 between both lower ends of the groove 220. The width W1 of the groove 220 may be about 1 mm to about 100 mm, but is not limited thereto.

In example embodiments, the slanted structure may be formed on the lower surface 212 of the showerhead body 210. Further, the groove 220 may be formed on the slanted lower surface 212 of the showerhead body 210. Thus, the slanted structure and the groove 220 may provide the showerhead 200 with an asymmetrical pattern. The asymmetrical pattern of the showerhead 200 may reduce a non-uniform distribution of the plasma on the horizontal plane. As a result, a shape and a position of the asymmetrical pattern of the showerhead 200 (i.e., a shape and a position of the slanted structure and the groove 220) may be changed to reduce non-uniform distribution of the plasma.

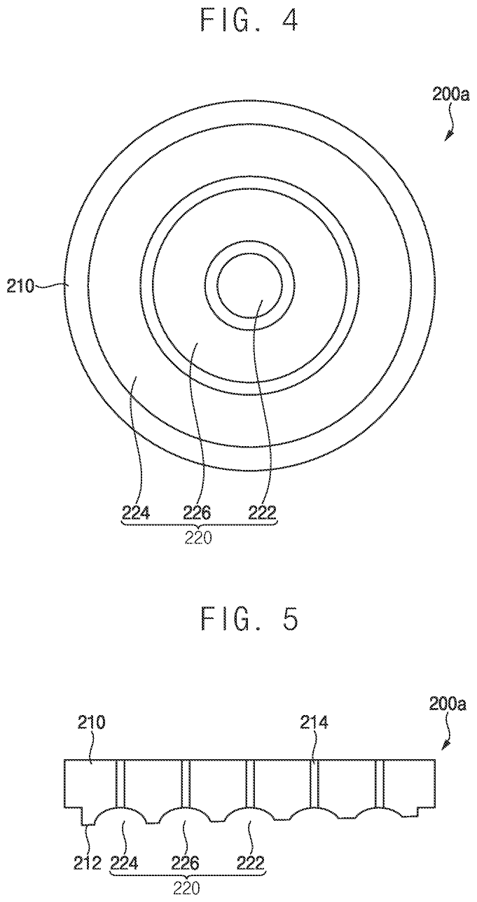

FIG. 4 is a bottom view illustrating a showerhead according to one or more example embodiments. FIG. 5 is a cross-sectional view illustrating the showerhead in FIG. 4 according to one or more example embodiments.

A showerhead 200a according to example embodiments may include elements substantially the same as those of the showerhead 200 in FIGS. 2 and 3 except for a groove. Thus, the same reference numerals may refer to the same elements and any further illustrations with respect to the same elements may be omitted herein for brevity.

Referring to FIGS. 4 and 5, a showerhead 200a according to example embodiments may include a plurality of grooves 220. The plurality of grooves 220 may include a first groove 222, a second groove 224 and a third groove 226.

The first groove 222 may be formed on a central portion of the lower surface 212 of the showerhead body 210. The first groove 222 may have a circular shape on the horizontal plane, but is not limited thereto.

The second groove 224 may be formed on an edge portion of the lower surface 212 of the showerhead body 210. Thus, the second groove 224 may surround or at least partially surround the first groove 222. The second groove 224 may have an annular shape on the horizontal plane, but is not limited thereto.

The third groove 226 may be formed on a middle portion of the showerhead body 210 between the central portion and the edge portion. Thus, the third groove 226 may be positioned between the first groove 222 and the second groove 224. The third groove 226 may have an annular shape on the horizontal plane, but is not limited thereto.

Further, the first groove 222, the second groove 224 and the third groove 226 may have upper ends positioned on a same horizontal plane. The first groove 222, the second groove 224 and the third groove 226 may have lower surfaces exposed through the slanted lower surface 212 of the showerhead body 210. Thus, the first groove 222, the second groove 224 and the third groove 226 may have different depths. That is, the depth of the third groove 226 may be deeper than the depth of the first groove 222. The depth of the second groove 224 may be deeper than the depth of the third groove 226.

In example embodiments, the showerhead 200a may include the three grooves, but is not limited thereto. For example, the showerhead 200a may include two or at least four grooves.

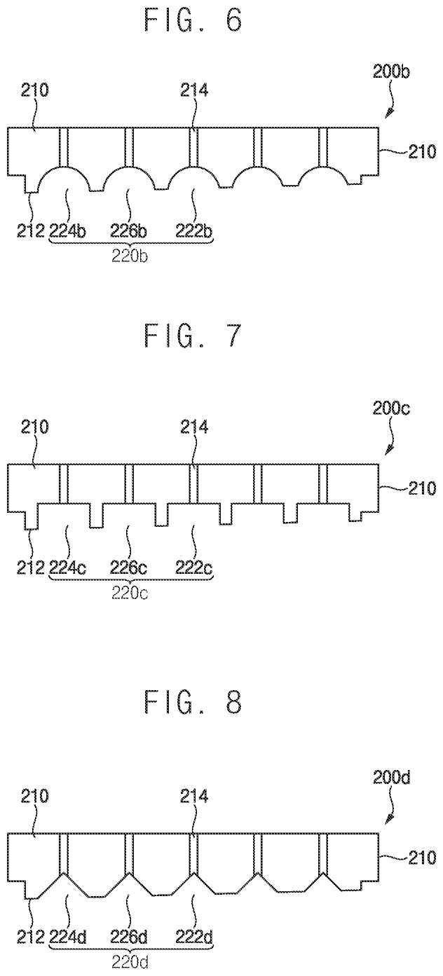

FIG. 6 is a cross-sectional view illustrating a showerhead according to one or more example embodiments.

A showerhead 200b according to example embodiments may include elements substantially the same as those of the showerhead 200a in FIG. 5 except for a shape of a groove. Thus, the same reference numerals may refer to the same elements and any further illustrations with respect to the same elements may be omitted herein for brevity.

Referring to FIG. 6, the showerhead 200b according to example embodiments may include a plurality of grooves 220b. The plurality of grooves 220b may have a semi-circular shape. That is, a first groove 222b, a second groove 224b and a third groove 226b may have semi-circular shapes.

FIG. 7 is a cross-sectional view illustrating a showerhead according to one or more example embodiments.

A showerhead 200c according to example embodiments may include elements substantially the same as those of the showerhead 200a in FIG. 5 except for a shape of a groove. Thus, the same reference numerals may refer to the same elements and any further illustrations with respect to the same elements may be omitted herein for brevity.

Referring to FIG. 7, the showerhead 200c according to example embodiments may include a plurality of grooves 220c, and the plurality of grooves 220c may have a rectangular shape. That is, a first groove 222c, a second groove 224c and a third groove 226c may have rectangular shapes.

FIG. 8 is a cross-sectional view illustrating a showerhead according to one or more example embodiments.

A showerhead 200d according to example embodiments may include elements substantially the same as those of the showerhead 200a in FIG. 5 except for a shape of a groove. Thus, the same reference numerals may refer to the same elements and any further illustrations with respect to the same elements may be omitted herein for brevity.

Referring to FIG. 8, the showerhead 200d according to example embodiments may include a plurality of grooves 220d, and the plurality of grooves 220d may have a triangular shape. That is, a first groove 222d, a second groove 224d and a third groove 226d may have triangular shapes.

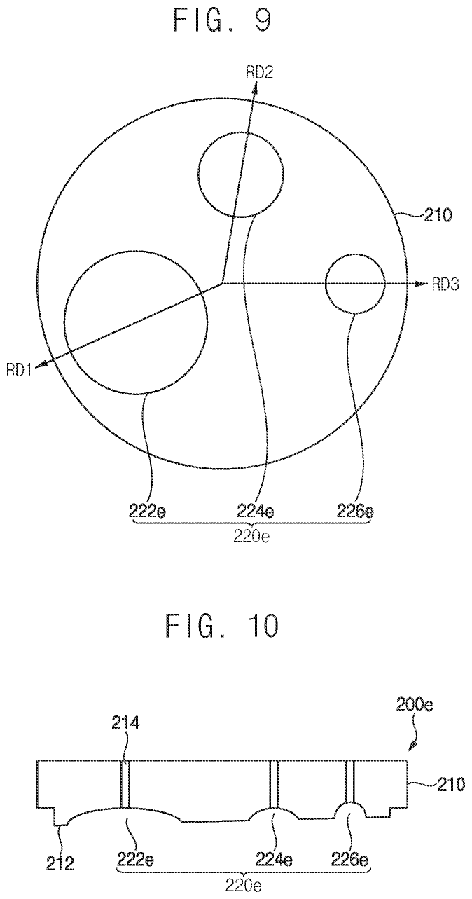

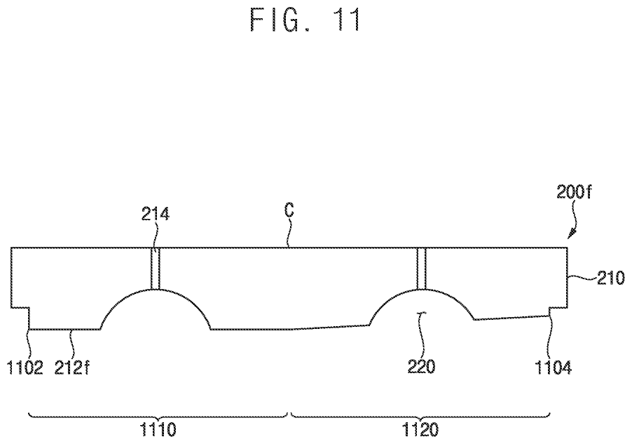

FIG. 9 is a bottom view illustrating a showerhead according to one or more example embodiments. FIG. 10 is a cross-sectional view illustrating the showerhead in FIG. 9 according to one or more example embodiments.

A showerhead 200e according to example embodiments may include elements substantially the same as those of the showerhead 200 in FIGS. 2 and 3 except for a groove. Thus, the same reference numerals may refer to the same elements and any further illustrations with respect to the same elements may be omitted herein for brevity.

Referring to FIGS. 9 and 10, the showerhead 200e according to example embodiments may include a plurality of grooves 220e. The plurality of grooves 220e may include a first groove 222e, a second groove 224e and a third groove 226e.

The first groove 222e may be positioned along a first radial direction RD1 from the center point of the showerhead body 210. The first groove 222e may have a circular shape on the horizontal plane, but is not limited thereto.

The second groove 224e may be positioned along a second radial direction RD2 from the center point of the showerhead body 210. The second radial direction RD2 may be different from the first radial direction RD1. Thus, the second groove 224e may have a circular shape on the horizontal plane, but is not limited thereto. Further, the second groove 224e may have a size smaller than a size of the first groove 222e, but is not limited thereto.

The third groove 226e may be positioned along a third radial direction RD3 from the center point of the showerhead body 210. The third radial direction RD3 may be different from the first radial direction RD1 and the second radial direction RD2. Thus, the third groove 226e may have a circular shape on the horizontal plane, but is not limited thereto. Further, the third groove 226e may have a size smaller than the size of the second groove 224e, but is not limited thereto.

That is, in example embodiments, the first groove 222e, the second groove 224e and the third groove 226e may have the different sizes on the horizontal plane, but are not limited thereto. For example, the first groove 222e, the second groove 224e and the third groove 226e may have substantially the same size on the horizontal plane. Further, the size of the second groove 224e may be larger than the size of the first groove 222e. The size of the third groove 226e may be larger than the size of the second groove 224e.

FIG. 11 is a cross-sectional view illustrating a showerhead according to one or more example embodiments.

A showerhead 200f according to example embodiments may include elements substantially the same as those of the showerhead 200 in FIG. 3 except for a slanted structure. Thus, the same reference numerals may refer to the same elements and any further illustrations with respect to the same elements may be omitted herein for brevity.

Referring to FIG. 11, a slanted structure according to example embodiments may be partially formed on the lower surface 212f of the showerhead body 210. For example, the slanted structure may extend from the center point of the showerhead body 210 along the radial direction of the showerhead body 210 on the lower surface of the showerhead body 210, but is not limited thereto. As such, the lower surface 212f of the showerhead body 210 may include a first portion 1110 that is not slanted and that extends from the center point C of the showerhead body 210 to the left end section 1102 and a second portion 1120 that is slanted and that extends from the center point C of the showerhead body 210 to the right end section 1104.

According to example embodiments, the slanted structure and the groove on the lower surface of the showerhead body may provide the showerhead with the asymmetrical pattern. The asymmetrical pattern of the showerhead may control the asymmetrical distribution of the plasma on the horizontal plane in the reaction chamber and the plasma distribution in a specific region along the radial direction of the showerhead. Thus, the plasma may have a uniform distribution to form a layer having a uniform thickness on the substrate or to etch a layer on the substrate by a uniform thickness.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A showerhead comprising:
a showerhead body positioned at an upper surface of a reaction chamber and configured to inject a reaction gas toward a substrate in the reaction chamber; and
at least one groove in a lower surface of the showerhead body,
wherein the showerhead body is oriented toward the substrate, and
wherein the lower surface of the showerhead body comprises a slanted structure.

2. The showerhead of claim 1, wherein the slanted structure extends along an entirety of the lower surface of the showerhead body.

3. The showerhead of claim 2, wherein the slanted structure extends along the entirety of the lower surface of the showerhead body along a diameter line of the showerhead body.

4. The showerhead of claim 1, wherein the lower surface of the showerhead body comprises a first portion that comprises the slanted structure and a second portion that does not comprise the slanted structure.

5. The showerhead of claim 4, wherein the first portion the lower surface of the showerhead body that comprises the slanted structure extends from a center point of the showerhead body along a radial direction of the showerhead body.

6. The showerhead of claim 1, wherein the at least one groove comprises:
a first groove in a central portion of the lower surface of the showerhead body; and
a second groove in an edge portion of the lower surface of the showerhead body, and
wherein the second groove at least partially surrounds the first groove.

7. The showerhead of claim 6, wherein the at least one groove further comprises a third groove between the central portion and the edge portion on the lower surface of the showerhead body, such that the third groove is positioned between the first groove and the second groove.

8. The showerhead of claim 7, wherein the first groove has a circular shape on a horizontal plane, and
wherein the second groove and the third groove have annular shapes on the horizontal plane.

9. The showerhead of claim 7, wherein the first groove, the second groove and the third groove have different depths along a vertical direction of the showerhead body.

10. The showerhead of claim 1, wherein the at least one groove comprises a plurality of grooves positioned on different radial directions from a center point of the showerhead body.

11. The showerhead of claim 10, wherein the plurality of grooves comprises:
a first groove positioned along a first radial direction from the center point of the showerhead body;
a second groove positioned along a second radial direction from the center point of the showerhead body, the second radial direction being different from the first radial direction; and
a third groove positioned along a third radial direction from the center point of the showerhead body, the third radial direction being different from the first radial direction and the second radial direction.

12. The showerhead of claim 11, wherein the first groove, the second groove and the third groove have different sizes.

13. The showerhead of claim 1, wherein the at least one groove has a semi-elliptical shape, a semi-circular shape, a rectangular shape or a triangular shape.

14. The showerhead of claim 1, further comprising a plurality of injection holes extending from an upper surface of the showerhead body to the at least one groove,
wherein the plurality of injection holes are configured to inject the reaction gas.

15. A showerhead comprising:
a showerhead body positioned at an upper surface of a reaction chamber and configured to inject a reaction gas toward a substrate in the reaction chamber; and
at least one groove in a lower surface of the showerhead body,
wherein the showerhead body is oriented toward the substrate,
wherein the lower surface of the showerhead body comprises a slanted structure, and
wherein the at least one groove comprises:
a first groove in a central portion of the lower surface of the showerhead body;
a second groove in an edge portion of the lower surface of the showerhead body, the second groove at least partially surrounding the first groove; and
a third groove between the central portion and the edge portion in the lower surface of the showerhead body, such that the third groove is positioned between the first groove and the second groove.

16. The showerhead of claim 15, wherein the first groove has a circular shape on a horizontal plane, and
wherein the second groove and the third groove have annular shapes on the horizontal plane.

17. The showerhead of claim 15, wherein the first groove, the second groove and the third groove have different depths along a vertical direction of the showerhead body.

18. The showerhead of claim 15, wherein the at least one groove has a semi-elliptical shape, a semi-circular shape, a rectangular shape or a triangular shape.

19. An apparatus for processing a substrate, the apparatus comprising:
a reaction chamber configured to receive the substrate;
an electrostatic chuck (ESC) in the reaction chamber and configured to support the substrate; and
a showerhead positioned at an upper surface of the reaction chamber and configured to inject a reaction gas toward the substrate,
wherein the showerhead comprises:
a showerhead body oriented toward the substrate; and
at least one groove in a lower surface of the showerhead body, and
wherein the lower surface of the showerhead body comprises a slanted structure.

20. The apparatus of claim 19, further comprising a focus ring on the ESC and configured to at least partially surround the substrate.
